(19) United States
(12) Patent Application Publication
(10) Pub. No.: US 2007/0089864 A1
(43) Pub. Date: Apr. 26, 2007

(54) HEAT PIPE WITH COMPOSITE WICK STRUCTURE

(75) Inventors: CHANG-SHEN CHANG, Tu-Cheng,Taipei Hsien (TW); JUEI-KHAI LIU, Tu-Cheng,Taipei Hsien (TW); KAI-FENG HSIAO, Tu-Cheng,Taipei Hsien (TW); CHAO-HAO WANG, Tu-Cheng,Taipei Hsien (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: FOXCONN TECHNOLOGY CO., LTD., Taipei Hsien (TW)

(21) Appl. No.: 11/309,301

(22) Filed: Jul. 24, 2006

(30) Foreign Application Priority Data
Oct. 24, 2005 (CN) 200510100598.2

(51) Int. Cl. H05K 7/20

(52) U.S. Cl. 165/104.26; 165/104.33; 361/700

(57) ABSTRACT

A heat pipe (10) includes a longitudinal casing (12) having an evaporator section (121) and a condenser section (122), a major wick structure (14) disposed in an inner wall of the casing, at least one assistant wick structure (16) contacting with an inner wall of the major wick structure and extending between the evaporator section and the condenser section, and working medium filling the casing and saturating the major and assistant wick structures. A diameter of a cross section of the assistant wick structure is smaller than a diameter of a cross section of the major wick structure. The assistant wick structure cooperates with the major wick structure to form a composite wick structure, which increases the capillary force inside the heat pipe and further increases the heat transfer capability of the heat pipe.

### DESCRIPTION

1. Field of the Invention

The present invention relates generally to an apparatus for transfer or dissipation of heat from heat-generating components, and more particularly to a heat pipe applicable in electronic products such as personal computers for removing heat from electronic components installed therein.

2. Description of Related Art

Heat pipes have excellent heat transfer performance due to their low thermal resistance, and are therefore an effective means for transfer or dissipation of heat from heat sources. Currently, heat pipes are widely used for removing heat from heat-generating components such as central processing units (CPUs) of computers. A heat pipe is usually a vacuum casing containing therein a working medium, which is employed to carry, under phase transitions between liquid state and vapor state, thermal energy from one section of the heat pipe (typically referring to as the “evaporator section”) to another section thereof (typically referring to as the “condenser section”). Preferably, a wick structure is provided inside the heat pipe, lining an inner wall of the casing, for drawing the working medium back to the evaporator section after it is condensed at the condenser section. The wick structure currently available for the heat pipe includes fine grooves integrally formed at the inner wall of the casing, screen mesh or fiber inserted into the casing and held against the inner wall thereof, or sintered powders combined to the inner wall of the casing by sintering process.

In operation, the evaporator section of the heat pipe is maintained in thermal contact with a heat-generating component. The working medium contained at the evaporator section absorbs heat generated by the heat-generating component and then turns into vapor. Due to the difference of vapor pressure between the two sections of the heat pipe, the generated vapor moves and thus carries the heat towards the condenser section where the vapor is condensed into condensate after releasing the heat into ambient environment by, for example, fins thermally contacting the condenser section. Due to the difference in capillary pressure which develops in the wick structure between the two sections, the condensate is then brought back by the wick structure to the evaporator section where it is again available for evaporation.

In order to draw the condensate back timely, the wick structure provided in the heat pipe is expected to provide a high capillary force and meanwhile generate a low flow resistance for the condensate. In ordinary use, the heat pipe needs to be flattened to enable the miniaturization of electronic products, which results in the wick structure of the heat pipe being damaged. Therefore, the flow resistance of the wick structure is increased and the capillary force provided by the wick structure is decreased, which reduces the heat transfer capability of the heat pipe. If the condensate is not quickly brought back from the condenser section, the heat pipe will suffer a dry-out problem at the evaporator section.

Therefore, it is desirable to provide a heat pipe with improved heat transfer capability, whose wick structure will not be damaged when the heat pipe is flattened.

### SUMMARY OF THE INVENTION

The present invention relates to a heat pipe for removing heat from heat-generating components. The heat pipe includes a longitudinal casing having an evaporator section and a condenser section, a major wick structure disposed in an inner wall of the casing, at least one assistant wick structure contacting with an inner wall of the major wick structure and extending between the evaporator section and the condenser section, and working medium filling the casing and saturating the major and the at least one assistant wick structures. A diameter of a cross section of the assistant wick structure is smaller than a diameter of a cross section of the major wick structure. The at least one assistant wick structure cooperates with the major wick structure to form a composite wick structure, which increases the capillary force inside the heat pipe and further increases the heat transfer capability of the heat pipe. The at least one assistant wick structure has an elongated, tubular configuration.

Other advantages and novel features of the present invention will become more apparent from the following detailed description of preferred embodiment when taken in conjunction with the accompanying drawings, in which:

### BRIEF DESCRIPTION OF THE DRAWINGS

Many aspects of the present invention can be better understood with reference to the following drawings. The components in the drawings are not necessarily drawn to scale, the emphasis instead being placed upon clearly illustrating the principles of the present invention. Moreover, in the drawings, like reference numerals designate corresponding parts throughout the several views:

FIG. 1 is a longitudinal cross-sectional view of a heat pipe in accordance with a first embodiment of the present invention;

FIG. 2 is a transverse cross-sectional view of the heat pipe of FIG. 1;

FIG. 3 is a transverse cross-sectional view of a flat heat pipe in accordance with a second embodiment of the present invention;

FIG. 4 is a transverse cross-sectional view of a heat pipe in accordance with a third embodiment of the present invention;

FIG. 5a transverse cross-sectional view of a flat heat pipe in accordance with a fourth embodiment of the present invention; and

FIG. 6 is a transverse cross-sectional view of a heat pipe in accordance with a fifth embodiment of the present invention.

### DETAILED DESCRIPTION OF THE INVENTION

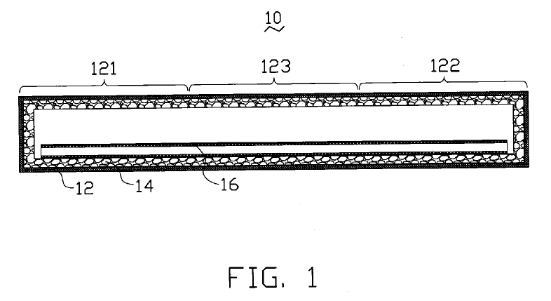

FIG. 1 illustrates a heat pipe 10 in accordance with a first embodiment of the present invention. The heat pipe 10 includes a round metal casing 12, and a variety of elements enclosed in the metal casing 12, i.e. a major wick structure 14, an assistant wick structure 16, and a working medium (not shown).

The metal casing 12 is made of high thermally conductive material such as copper or aluminum. The metal casing 12 has an evaporator section 121, an opposing condenser section 122 along a longitudinal direction of the heat pipe 10, and an adiabatic section 123 disposed between the evaporator and condenser sections 121, 122. The evaporator and condenser sections 121, 122 each occupy a respective end portion of the heat pipe 10. Two ends of the heat pipe 10 are sealed.

The working medium is saturated in the major and assistant wick structures 14, 16 and is usually selected from a liquid such as water, methanol, or alcohol, which has a low boiling point and is compatible with the major and assistant wick structures 14, 16. Thus, the working medium can easily evaporate to vapor when it receives heat at the evaporator section 121 of the heat pipe 10. The metal casing 12 of the heat pipe 10 is evacuated and hermetically sealed after the working medium is injected into the metal casing 12 and saturated in the major and assistant wick structures 14, 16.

The major wick structure 14 is evenly distributed around an inner wall of the metal casing 12 and extends along a longitudinal direction of the metal casing 12 of the heat pipe 10. The major wick structure 14 is tube-shaped in profile, and usually selected from a porous structure such as grooves, sintered powder, screen mesh, or bundles of fiber, which enables it to provide a capillary force to drive condensed working medium at the condenser section 122 of the heat pipe 10 to flow towards the evaporator section 121 thereof.

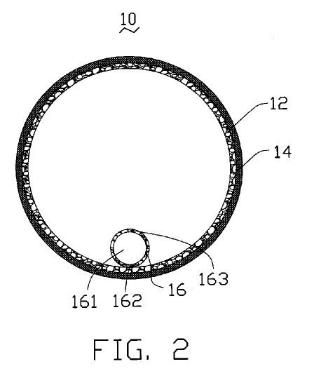

Particularly referring to FIG. 2, the assistant wick structure 16 is a longitudinal hollow tube, which is attached to an inner wall of the major wick structure 14 and extends along the longitudinal direction of the metal casing 12. The assistant wick structure 16 is woven by a plurality of metal wires, such as copper, or stainless steel wires. Alternatively, the assistant wick structure 16 may be sintered by an amount of powders. A channel 161 is defined in an inner space of the assistant wick structure 16 for passage of vaporized working medium. A plurality of pores (not shown) are formed in a peripheral wall of the assistant wick structure 16, which provides a capillary action to the working medium and communicates the assistant wick structure 16 with the major wick structure 14. A composite wick structure is thus formed in the metal casing 12 of the heat pipe 10. The assistant wick structure 16 has a ring-like transverse cross section. A diameter of the assistant wick structure 16 is smaller than a diameter of the major wick structure 14. The assistant wick structure 16 has an adjacent portion 162 contacting with the inner wall of the major wick structure 14, and a distal portion 163 spaced a distance from the inner wall of the major wick structure 14 along a radial direction of the heat pipe 10.

In operation, the evaporator section 121 of the heat pipe 10 is placed in thermal contact with a heat source (not shown), for example, a central processing unit (CPU) of a computer, that needs to be cooled. The working medium contained in the evaporator section 121 of the heat pipe 10 is vaporized into vapor upon receiving the heat generated by the heat source. Then, the generated vapor moves via a space between the major and assistant wick structures 14, 16 and the channel 161 towards the condenser section 122 of the heat pipe 10. After the vapor releases the heat carried thereby and it is condensed into condensate in the condenser section 122, the condensate is brought back by the major wick structure 14 to the evaporator section 121 of the heat pipe 10 for being available again for evaporation. Meanwhile, the condensate resulting from the vapor in the condenser section 122 is capable of entering into the assistant wick structure 16 easily due to the capillary action of the assistant wick structure 16. As a result, the condensate is drawn back to the evaporator section 121 rapidly and timely, thus preventing a potential dry-out problem occurring at the evaporator section 121. In addition, the working medium can not be accumulated in a bottom portion of the major wick structure 14 of the heat pipe 10 under an action of gravity. This prevents the increase of the flow resistance of the heat pipe 10, which is caused by the accumulation of the working medium. The heat transfer capability of the heat pipe 10 is thus increased.

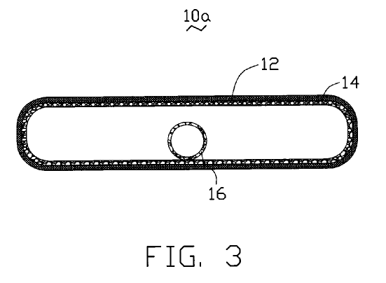

In the present invention, the assistant wick structure 16 cooperates with the major wick structure 14 to form the composite wick structure, which increases the capillary force inside the heat pipe 10. Thus, the heat transfer capability of the heat pipe 10 is increased. The assistant wick structure 16 is distributed along the longitudinal direction of the heat pipe 10 and has a smaller diameter than that of the major wick structure 14. As a result, the assistant wick structure 16 can not easily be damaged by the flattening process of the heat pipe 10. As shown in FIG. 3, a flat composite heat pipe 10a in accordance with a second embodiment of the present invention is obtained by flattening the heat pipe 10 of FIGS. 1 and 2, which has a round cross section. The heat transfer capability of the flat composite heat pipe 10a is not decreased too much due to the flattening operation. The heat transfer capability of the flat composite heat pipe 10a is better than the flat conventional grooved, sintered powder, screen mesh, or bundles of fiber heat pipe whose wick structure is damaged in the flattening process. Experimental data is provided to validate the effectiveness of the heat pipes having the composite wick structure in accordance with the present invention over the conventional heat pipes, when the heat pipes are round in section (Table 1) or flat in section (Table 2).

Table 1 below shows an average of maximum heat transfer quantities (Qmax) and an average of heat resistances (Rth) of forty-five conventional round grooved heat pipes and forty-five round heat pipes 10 of the present invention. Qmax represents the maximum heat transfer quantity of the heat pipe at an operational temperature of 50° C. Rth is obtained by dividing the margin between an average temperature of the evaporator section 121 of the heat pipe 10 and an average temperature of the condenser section 122 thereof by Qmax. A diameter of the transverse cross section and a longitudinal length of each of the conventional grooved heat pipes are 6 mm and 160 mm, which are equal to the transverse diameter and longitudinal length of each of the present heat pipes 10. Table 1 shows that the heat resistance of the round present heat pipe 10 is significantly less than that of the round conventional grooved heat pipe, whilst the Qmax of the round present heat pipe 10 is significantly more than that of the round conventional grooved heat pipe.

TABLE 1

| | Average of Qmax | Average of Rth |
|---|---|---|
| Heat pipe type | (unit: w) | (unit: ° C./w) |
| Grooved heat pipe | 65 | 0.025 |
| Present heat pipe | 89 | 0.023 |

Table 2 as below shows an average of maximum heat transfer quantities (Qmax) and an average of heat resistances (Rth) of ten conventional grooved, fiber, sintered powder, and present heat pipes 10a, which are flattened to a height of 3.0 mm. Before these heat pipes are flattened, they have the same transverse diameter and longitudinal length as the heat pipes mentioned in Table 1. Qmax and Rth in Table 2 have the same meaning as the Qmax and Rth in Table 1. Table 2 shows that the heat resistance of the flat present heat pipe 10a is significantly less than that of the flat conventional grooved, fiber, and sintered powder heat pipes, whilst the Qmax of the flat present heat pipes 10a is significantly more than that of the flat conventional grooved, fiber, and sintered powder heat pipes.

| | Average of Qmax | Average of Rth |
|---|---|---|
| Heat pipe type | (unit: w) | (unit: ° C./w) |
| Grooved heat pipe | 32 | 0.055 |
| Fiber heat pipe | 37.5 | 0.114 |
| Sintered powder heat pipe | 33.5 | 0.056 |
| Present heat pipe | 46.1 | 0.037 |

Studying for the experiment data shown in Tables 1 and 2, both the round and flat present heat pipe 10, 10a have better heat transfer capabilities than that of the conventional round and flat heat pipes. Moreover, the present heat pipe 10 can easily be batch produced by using a work station, where the assistant wick structure 16 is inserted into an inner space of the conventional heat pipe, in the product line for the conventional heat pipe.

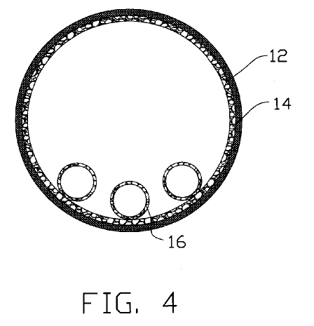

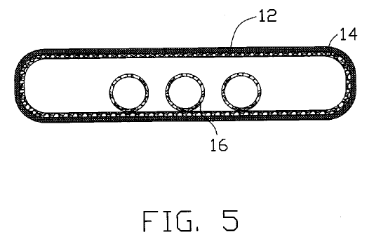

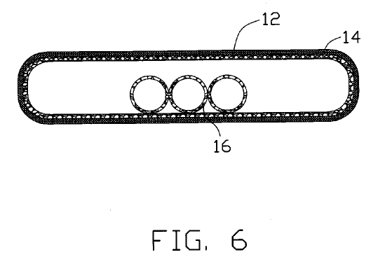

In the present invention, the heat pipe 10 may include more than one assistant wick structure 16. Theses assistant wick structures 16 may be tightly and tidily attached to the inner wall (shown in FIGS. 4 to 6) or loosely and mussily inserted into the inner space of the major wick structure 14. In addition, these assistant wick structures 16 may be spaced by a distance (FIGS. 4 and 5) or intimately contact (FIGS. 6) with each other. In the above embodiments from FIG. 1 to FIG. 6, the assistant wick structure 16 has a linear contact with the major wick structure 14.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat pipe comprising:
a longitudinal casing having an evaporator section and a condenser section, wherein vapor in the longitudinal casing flows from the evaporator section to the condenser section;
a major wick structure disposed in an inner wall of the casing;
at least one assistant wick structure contacting with an inner wall of the major wick structure and extending between the evaporator section and the condenser section, a diameter of a cross section of the at least one assistant wick structure being smaller than a diameter of a cross section of the major wick structure, the at least one assistant wick structure having a linear contact with the inner wall of the major wick structure; and
working medium filling the casing and saturating the major wick structure and the at least one assistant wick structure.

2. The heat pipe of claim 1, wherein the at least one assistant wick structure has an adjacent portion contacting with the inner wall of the major wick structure, and a distant portion spaced at a distance from the inner wall of the major wick structure.

3. The heat pipe of claim 1, wherein the at least one assistant wick structure is a hollow tube sintered with powder.

4. The heat pipe of claim 1, wherein the at least one assistant wick structure is a hollow tube woven by a plurality of metal wires.

5. The heat pipe of claim 4, wherein the metal wires is selected from a group consisting of copper wire and stainless steel wire.

6. The heat pipe of claim 1, wherein the at least one assistant wick structure is attached to the inner wall of the major wick structure.

7. The heat pipe of claim 1, wherein the at least one assistant wick structure is loosely inserted into an inner space of the major wick structure.

8. The heat pipe of claim 1, wherein the at least one assistant wick structure comprises a plurality of assistant wick structures spacing a distance with each other.

9. The heat pipe of claim 1, wherein the at least one assistant wick structure comprises a plurality of assistant wick structures contacting each other.

10. The heat pipe of claim 1, wherein the major structure is selected from the group of grooves, sintered powder, fiber and screen mesh.

11. A heat pipe comprising:
a metal casing;
a porous major wick structure disposed in an inner wall of the casing;
at least one assistant wick structure disposed in an inner wall of the major wick structure and defining a plurality of pores communicating with the major wick structure; and
working medium filling the casing and saturating the major wick structure and the at least one assistant wick structure;
wherein vapor in the metal casing flows from one end to an opposite end thereof via a space between the major wick structure and the at least one assist wick structure.

12. The heat pipe of claim 11, wherein the at least one assistant wick structure is a hollow tube extending along a longitudinal direction of the casing.

13. The heat pipe of claim 11, wherein the at least one assistant wick structure is woven from a plurality of metal wires selected from a group consisting of copper and stainless steel wires.

14. The heat pipe of claim 11, wherein the at least one assistant wick structure comprises a plurality of assistant wick structures spaced from each other or contacting with each other.

15. The heat pipe of claim 11, wherein the at least one assistant wick structure is tightly attached to the inner wall or loosely inserted into an inner space of the major wick structure.

16. The heat pipe of claim 11, wherein the metal casing has one of following shapes: round shape and flat shape, and the at least one assistant wick structure has a round shape.

17. The heat pipe of claim 12, wherein the vapor also flows through a channel defined in the at least one assistant wick structure from the one end to the opposite end of the metal casing.

18. The heat pipe of claim 12, wherein the at least one assistant wick structure has a linear contact with the inner wall of the major wick structure.
